(19) United States
(12) Patent Application Publication
(10) Pub. No.: US 2024/0161815 A1
(43) Pub. Date: May 16, 2024

(54) DUAL PORT DUAL POWER RAIL MEMORY ARCHITECTURE

(71) Applicant: NVIDIA Corp., Santa Clara, CA (US)

(72) Inventors: Lalit Gupta, FREMONT, CA (US); Jason Golbus, Palo Alto, CA (US); Jesse San-Jey Wang, Santa Clara, CA (US)

(73) Assignee: NVIDIA Corp., Santa Clara, CA (US)

(21) Appl. No.: 18/055,047

(22) Filed: Nov. 14, 2022

(51) Int. Cl. G11C 11/4096; G11C 11/4076; G11C 11/4094

(52) U.S. Cl. CPC G11C 11/4096; G11C 11/4076; G11C 11/4094

(57) ABSTRACT

Multi-ported memories that include write peripheral logic configured to operate in a first voltage domain, read peripheral logic configured to operate in a second voltage domain, and at least one bit cell array, wherein the write peripheral logic and the read peripheral logic are disposed on opposite sides of the bit cell array and voltage domain crossings between the first voltage domain and the second voltage domain are localized in bit cells of the at least one bit cell array.

### BACKGROUND

Multi-ported memories are utilized in many digital devices to enable reads and writes to be performed in overlapping time intervals, unlike single-ported memory devices that enable only one memory access (read or write) to take place at a given time.

For example, video random access memory (VRAM) is a type of multi-ported dynamic random access memory (RAM) that enables a machine processor to write graphics information to memory at the same time the video hardware is reading out graphics information for display.

Very large scale integrated (VLSI) circuit design is subject to constraints on the spacing of n-wells in complementary metal-oxide semiconductor (CMOS) circuits to prevent voltage bleed-through between circuit elements, such as transistors. The N-well spacing constraints increase between CMOS devices, e.g., P-channel field effect transistors (PFETs) that are operated at different voltage potentials, based on the extent of the maximum potential difference the devices may be subjected to in operation.

In conventional multi-ported memories, the ports may operate in the same voltage domain (i.e., powered by a same supply voltage). For example, in a dual-ported memory device both of the read and write peripheral logic may operate at the same supply voltage. The read and write peripheral logic may also operate in the same clock domain (i.e., driven by the same clock).

Additional design constraints may arise in memory devices wherein the ports are operated at different supply voltages and/or different clock domains.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 depicts an eight transistor bit storage cell 100 in one embodiment.

FIG. 2 depicts a memory device 200 in one embodiment.

FIG. 3A depicts an embodiment of a memory device 300a.

FIG. 3B depicts a signal pin interface 300b for a memory device in accordance with one embodiment.

FIG. 3C depicts an embodiment of a memory device 300c.

FIG. 4A depicts localization of voltage domain crossings in a bit cell of a memory device in accordance with one embodiment.

FIG. 4B illustrates an aspect of the subject matter in accordance with one embodiment.

FIG. 5 depicts a signal pin interface for a dual-ported memory device 502 in accordance with one embodiment.

FIG. 6 depicts a circuit system 602 in accordance with one embodiment.

### DETAILED DESCRIPTION

A multi-ported memory device may utilize two or more distinct input/output (IO) ports to read and write data to and from the memory during overlapping time intervals, using different clock domains for read and write operations. In addition to utilizing different clock domains, memories of this type may also utilize different voltage domains for the read peripheral logic and the write peripheral logic. A clock signal for the read peripheral logic of a memory device is referenced herein as CLK_R, and a clock for the write peripheral logic of a memory device is referenced herein as CLK_W. Supply voltages for the read logic voltage domain and the write logic voltage domain are referenced herein as VDD_R and VDD_W, respectively.

The use of different voltage domains for the read logic and the write logic creates design and layout constraints, such as constraints on hot N-well spacing for semiconductor elements to account for maximal potential differences between peripheral circuit elements in different voltage domains (e.g., when VDD_W is OFF and VDD_R is ON, or vice versa). When the read and write peripheral logic is co-located on the circuit layout, meeting these constraints may involve a substantial increase in circuit area and other complications. The different voltage domains may cross in the peripheral logic of the memory array, resulting in a need for one or more voltage level-shifting circuit between the domains, which is inefficient. Further, the use of different clock domains for different IO ports may give rise to constraints on clock-domain crossing in the peripheral logic.

Embodiments of a multi-ported memory are disclosed utilizing multiple voltage domains that avoid voltage level-shifting circuits and voltage domain crossings in the peripheral logic of a bit cell array. These embodiments also enable use of different clock domains for the read peripheral logic and the write peripheral logic.

In one aspect, voltage domain crossings for a multi-ported memory are localized in an NFET subnet of the bit storage cells themselves, e.g., at a gate of an NFET of a read bitline driver. The need for a voltage level-shifting circuit in the peripheral logic of the bit cell array is obviated. For example in a dual-ported memory device, the clock signals CLK_R and CLK_W for the read peripheral logic and the write peripheral logic respectively may have different frequencies, and the supply voltages VDD_R and VDD_W for the read logic and the write logic respectively may also be different.

In another aspect, the read peripheral logic may be segregated from the write peripheral logic by placement of these components on opposite sides of the bit cell array in the memory device layout. This may alleviate N-well spacing constraints (and hence circuit area of the peripheral logic) and pin congestion, and may also reduce the routing length of the read bitline (herein, “rblb”) and hence improve the read performance of the memory device.

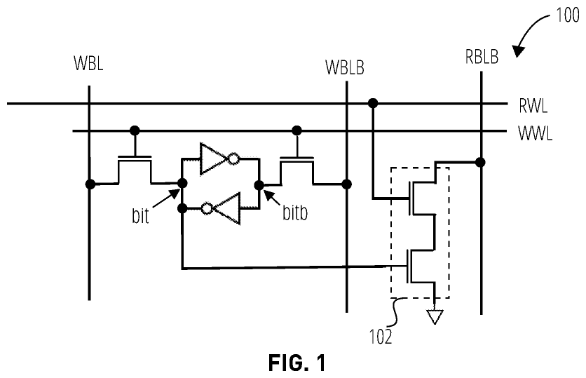

FIG. 1 depicts an eight transistor bit storage cell 100 in one embodiment. The eight transistor bit storage cell 100 comprises a pair of cross-coupled inverters storing a value of a bit, and a complement value (bitb) of the bit. A bit to store into the cell (write) and its complement are provided on the WBL and WBLB lines and the write word line WWL is operated on two passgate transistors to effect the storage of the bit in the bit cell. The read word line RWL is operated on the read bitline driver 102 to read a stored bit onto the read bitline RBLB.

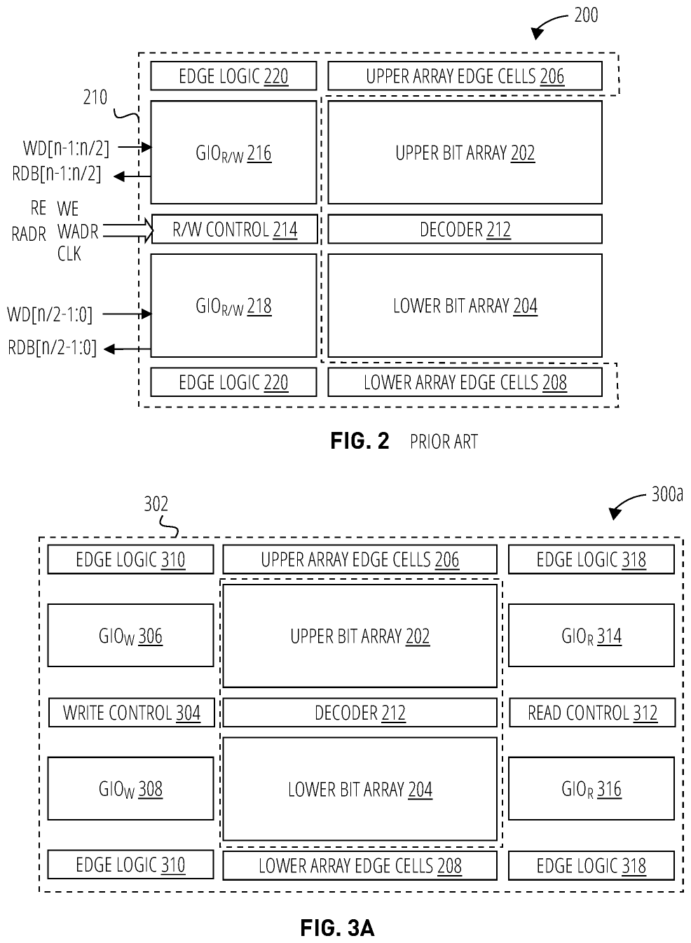

FIG. 2 depicts a memory device 200 in one embodiment. The memory device 200 comprises an upper bit array 202 and a lower bit array 204 for storing bits. Upper array edge cells 206 and lower array edge cells 208 provide various passgates and control and/or data lines into the bit cell array for reading and writing (e.g., read bitlines and write bitlines). Addresses for the bit cells to read from or write to are input to the peripheral logic 210 of the memory device 200 and translated into bit cell locations by the decoder 212.

The peripheral logic 210 of the memory device 200 comprises integrated read/write controller 214 providing the control signals for both reading from and writing to the upper bit array 202 and lower bit array 204. The integrated read/write controller 214 generates the control signals to the bit cell arrays based on read enable (RE), write enable (WE), read address (RADR), write address (WADR), and clock (CLK) signals that it receives, where the same clock is used for both reading and writing.

The peripheral logic 210 further comprises integrated IO port logic 216 (where GIO is short for “general input/output”) for writing or reading the most significant bits (WD[n−1:n/2], RDB[n−1:n/2]) of a word of bits, and integrated IO port logic 218 for writing or reading the least significant bits (WD[n/2−1:0], RDB[n/2−1:0]) of a word of bits. The peripheral logic 210 also comprises edge logic 220 for interfacing with the control and data lines in the upper array edge cells 206 and lower array edge cells 208.

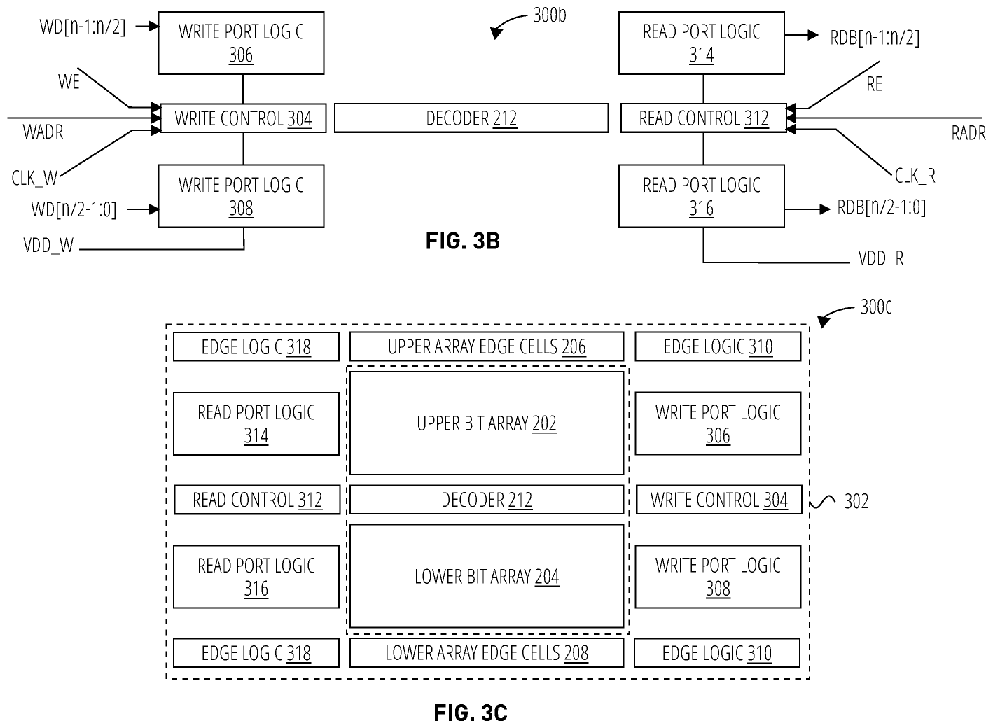

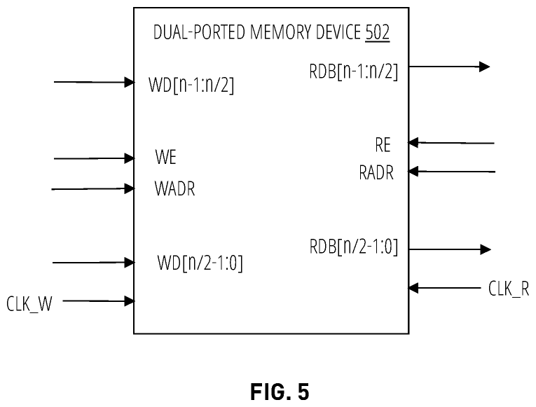

FIG. 3A and FIG. 3C depict embodiments of a memory device 300a and a memory device 300c wherein the peripheral logic 302 comprising write peripheral logic (write controller 304, write port logic 306, write port logic 308, and write peripheral edge logic 310) and read peripheral logic (read controller 312, read port logic 314, read port logic 316, and read peripheral edge logic 318) are de-integrated and separated onto opposite sides of the bit cell arrays 202, 204. As depicted in the signal pin interface 300b example of FIG. 3B and the chip-level depiction of a dual-ported memory device 502 in FIG. 5, the control signals for reading and writing are also separated onto opposite sides of the decoder 212 and bit cell arrays.

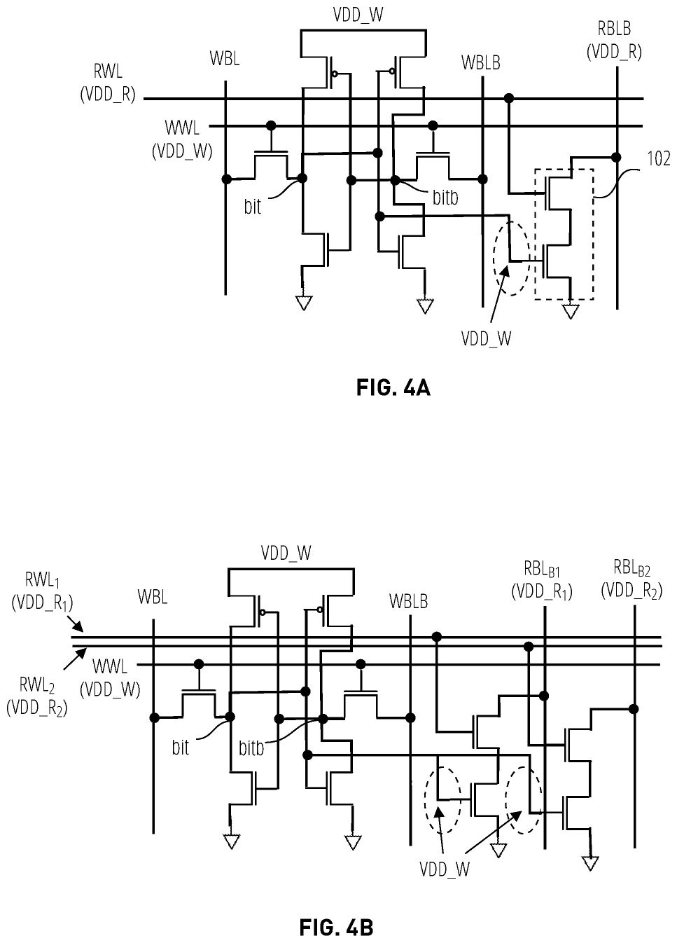

The write peripheral logic and read peripheral logic are operated in different voltage domains, without any voltage domain crossing or voltage level-shifting circuits utilized in the peripheral logic. As may be seen in FIG. 4A, voltage domain crossings are localized in each of the bit cells of the bit cell arrays, at a gate of transistors in the read bitline driver 102, which is a dynamic element comprising, in this example, a stack of two NFETs with their channels coupled in series between the read bitline and circuit ground.

The mechanisms disclosed herein may be readily extended to memory devices with more than two ports, e.g., with a write port and multiple read ports each operating in different voltage domains. For example FIG. 4B depicts an example of a bit cell for memory devices comprising a write port and two read ports, each operating in a different voltage domain.

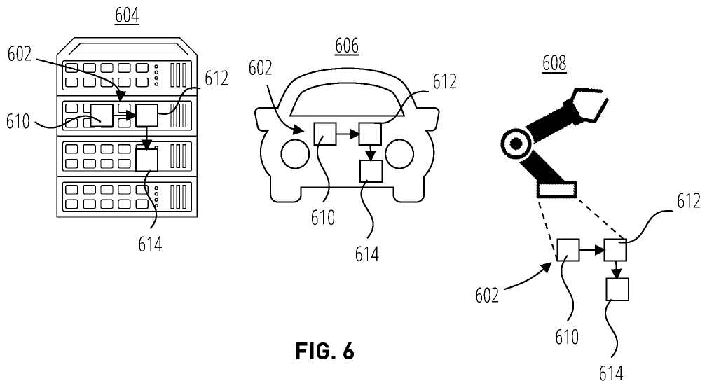

FIG. 6 depicts exemplary scenarios for use of a circuit system 602 in accordance with some embodiments. A circuit system 602 may be utilized in a computing system 604, a vehicle 606, and a robot 608, to name just a few examples. The circuit system 602 may comprise a first circuit 610 writing data to a write port of a dual-ported memory chip 612 and operating in a write voltage domain, and a second circuit 614 reading data from a read port of the dual-ported memory chip 612 and operating in a read voltage domain different than the write voltage domain.

### LISTING OF DRAWING ELEMENTS

100 eight transistor bit storage cell
102 read bitline driver
200 memory device
202 upper bit array
204 lower bit array
206 upper array edge cells
208 lower array edge cells
210 peripheral logic
212 decoder
214 integrated read/write controller
216 integrated IO port logic
218 integrated IO port logic
220 edge logic
300a memory device
300c memory device
300b signal pin interface
302 peripheral logic
304 write controller
306 write port logic
308 write port logic
310 write peripheral edge logic
312 read controller
314 read port logic
316 read port logic
318 read peripheral edge logic
502 dual-ported memory device
602 circuit system
604 computing system
606 vehicle
608 robot
610 first circuit
612 dual-ported memory chip
614 second circuit

Various functional operations described herein may be implemented in logic that is referred to using a noun or noun phrase reflecting said operation or function. For example, an association operation may be carried out by an “associator” or “correlator”. Likewise, switching may be carried out by a “switch”, selection by a “selector”, and so on. “Logic” refers to machine memory circuits and non-transitory machine readable media comprising machine-executable instructions (software and firmware), and/or circuitry (hardware) which by way of its material and/or material-energy configuration comprises control and/or procedural signals, and/or settings and values (such as resistance, impedance, capacitance, inductance, current/voltage ratings, etc.), that may be applied to influence the operation of a device. Magnetic media, electronic circuits, electrical and optical memory (both volatile and nonvolatile), and firmware are examples of logic. Logic specifically excludes pure signals or software per se (however does not exclude machine memories comprising software and thereby forming configurations of matter).

Within this disclosure, different entities (which may variously be referred to as “units,” “circuits,” other components, etc.) may be described or claimed as “configured” to perform one or more tasks or operations. This formulation—[entity] configured to [perform one or more tasks]—is used herein to refer to structure (i.e., something physical, such as an electronic circuit). More specifically, this formulation is used to indicate that this structure is arranged to perform the one or more tasks during operation. A structure can be said to be “configured to” perform some task even if the structure is not currently being operated. A “credit distribution circuit configured to distribute credits to a plurality of processor cores” is intended to cover, for example, an integrated circuit that has circuitry that performs this function during operation, even if the integrated circuit in question is not currently being used (e.g., a power supply is not connected to it). Thus, an entity described or recited as “configured to” perform some task refers to something physical, such as a device, circuit, memory storing program instructions executable to implement the task, etc. This phrase is not used herein to refer to something intangible.

The term “configured to” is not intended to mean “configurable to.” An unprogrammed FPGA, for example, would not be considered to be “configured to” perform some specific function, although it may be “configurable to” perform that function after programming.

Reciting in the appended claims that a structure is “configured to” perform one or more tasks is expressly intended not to invoke 35 U.S.C. § 112(f) for that claim element. Accordingly, claims in this application that do not otherwise include the “means for” [performing a function] construct should not be interpreted under 35 U.S.C § 112(f).

As used herein, the term “based on” is used to describe one or more factors that affect a determination. This term does not foreclose the possibility that additional factors may affect the determination. That is, a determination may be solely based on specified factors or based on the specified factors as well as other, unspecified factors. Consider the phrase “determine A based on B.” This phrase specifies that B is a factor that is used to determine A or that affects the determination of A. This phrase does not foreclose that the determination of A may also be based on some other factor, such as C. This phrase is also intended to cover an embodiment in which A is determined based solely on B. As used herein, the phrase “based on” is synonymous with the phrase “based at least in part on.”

As used herein, the phrase “in response to” describes one or more factors that trigger an effect. This phrase does not foreclose the possibility that additional factors may affect or otherwise trigger the effect. That is, an effect may be solely in response to those factors, or may be in response to the specified factors as well as other, unspecified factors. Consider the phrase “perform A in response to B.” This phrase specifies that B is a factor that triggers the performance of A. This phrase does not foreclose that performing A may also be in response to some other factor, such as C. This phrase is also intended to cover an embodiment in which A is performed solely in response to B.

As used herein, the terms “first,” “second,” etc. are used as labels for nouns that they precede, and do not imply any type of ordering (e.g., spatial, temporal, logical, etc.), unless stated otherwise. For example, in a register file having eight registers, the terms “first register” and “second register” can be used to refer to any two of the eight registers, and not, for example, just logical registers 0 and 1.

When used in the claims, the term “or” is used as an inclusive or and not as an exclusive or. For example, the phrase “at least one of x, y, or z” means any one of x, y, and z, as well as any combination thereof.

As used herein, a recitation of “and/or” with respect to two or more elements should be interpreted to mean only one element, or a combination of elements. For example, “element A, element B, and/or element C” may include only element A, only element B, only element C, element A and element B, element A and element C, element B and element C, or elements A, B, and C. In addition, “at least one of element A or element B” may include at least one of element A, at least one of element B, or at least one of element A and at least one of element B. Further, “at least one of element A and element B” may include at least one of element A, at least one of element B, or at least one of element A and at least one of element B.

The subject matter of the present disclosure is described with specificity herein to meet statutory requirements. However, the description itself is not intended to limit the scope of this disclosure. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Having thus described illustrative embodiments in detail, it will be apparent that modifications and variations are possible without departing from the scope of the invention as claimed. The scope of inventive subject matter is not limited to the depicted embodiments but is rather set forth in the following Claims.

What is claimed is:

1. A multi-ported memory device comprising:
write peripheral logic configured to operate in a first voltage domain;
read peripheral logic configured to operate in a second voltage domain;
at least one bit cell array;
wherein the write peripheral logic and the read peripheral logic are disposed on opposite sides of the bit cell array; and
wherein voltage domain crossings between the first voltage domain and the second voltage domain are localized in bit cells of the at least one bit cell array.

2. The multi-ported memory device of claim 1, further comprising:
a read bitline configured to run between the read peripheral logic and the bit cell array.

3. The multi-ported memory device of claim 1, wherein the bit cells are eight transistor bit cells.

4. The multi-ported memory device of claim 1, wherein the voltage domain crossings are localized at read bitline drivers of the bit cells.

5. The multi-ported memory device of claim 4, wherein the read bitline drivers comprise a stack of N-channel field effect transistors (NFETs).

6. The multi-ported memory device of claim 5, wherein the voltage domain crossings are localized at gates of the NFETs.

7. The multi-ported memory device of claim 1, further comprising:
a first clock domain;
a second clock domain; and
the write peripheral logic configured to operate in the first clock domain and the read peripheral logic configured to operate in the second clock domain.

8. A multi-ported memory device comprising:
a plurality of bit cell arrays;
at least one write port formed on a first edge of the bit cell arrays;
at least one read port formed on a second edge of the bit cell arrays opposite the first edge;
the at least one write port and the at least one read port configured to operate in different voltage domains; and
wherein voltage domain crossings between the first voltage domain and the different voltage domains are localized in N-type metal-oxide-semiconductor (NMOS) subnets of the bit cells.

9. The multi-ported memory device of claim 8, wherein the bit cells are eight transistor bit cells.

10. The multi-ported memory device of claim 8, wherein the voltage domain crossings are localized at read bitline drivers of the bit cells.

11. The multi-ported memory device of claim 8, wherein the NMOS subnets comprise a stack of N-channel field effect transistors (NFETs).

12. The multi-ported memory device of claim 11, wherein the voltage domain crossings are localized at gates of the NFETs.

13. The multi-ported memory device of claim 8, further comprising:
the at least one write port configured to operate in a first clock domain and the at least one read port configured to operate in a second clock domain that is asynchronous from the first clock domain.

14. A multi-ported memory device comprising:
a plurality of input/output (TO) ports each configured to operate in a different voltage domain;
a plurality of bit cells; and
wherein one or more read bitlines of the bit cells are configured to run between read peripheral logic on a first side of the bit cells, one or more write bitlines are configured to run on a second side of the bit cells opposite the first side, and voltage domain crossings are localized in the bit cells.

15. The multi-ported memory device of claim 14, wherein the bit cells are eight transistor bit cells.

16. The multi-ported memory device of claim 14, wherein the bit cells are ten transistor bit cells.

17. The multi-ported memory device of claim 14, wherein the voltage domain crossings are localized at read bitline drivers of the bit cells.

18. The multi-ported memory device of claim 17, wherein the read bitline drivers comprise a stack of N-channel field effect transistors (NFETs).

19. The multi-ported memory device of claim 18, wherein the voltage domain crossings are localized at gates of the NFETs.

20. The multi-ported memory device of claim 14, further comprising:
two or more of the TO ports configured to operate in different clock domains.
